(19) United States
(12) Patent Application Publication
(10) Pub. No.: US 2019/0295678 A1
(43) Pub. Date: Sep. 26, 2019

(54) SEMICONDUCTOR INTEGRATED CIRCUIT

(71) Applicants: Kabushiki Kaisha Toshiba, Minato-ku (JP); Toshiba Electronic Devices & Storage Corporation, Minato-ku (JP)

(72) Inventor: Kenichi ANZOU, Kawasaki (JP)

(73) Assignees: Kabushiki Kaisha Toshiba, Minato-ku (JP); Toshiba Electronic Devices & Storage Corporation, Minato-ku (JP)

(21) Appl. No.: 16/124,961

(22) Filed: Sep. 7, 2018

(30) Foreign Application Priority Data
Mar. 20, 2018 (JP) 2018-053258

(51) Int. Cl. G11C 29/38; G11C 29/36

(52) U.S. Cl. CPC G11C 29/38; G11C 29/36

(57) ABSTRACT

According to one embodiment, a semiconductor integrated circuit includes a memory, a BIST circuit, and a memory output analysis circuit. The memory output analysis circuit includes a first circuit, a second circuit, and a third circuit. The first circuit determines a first fault based on data outputted from the memory and an expected value. The second circuit determines whether or not the first fault corresponds to a second fault that continues in an address direction when he first fault is detected and outputs a first signal when the first fault corresponds to the second fault. The third circuit determines whether or not a third fault that does not correspond to the second fault occurs while the first signal is being outputted and outputs a second signal when determining that the third fault occurs. The BIST circuit determines interruption of a test based on the first and second signal.

### CROSS-REFERENCE TO RELATED APPLICATIONS

This application is based upon and claims the benefit of priority from Japanese Patent Application No. 2018-053258, filed on Mar. 20, 2018; the entire contents of which are incorporated herein by reference.

### FIELD

Embodiments described herein relate generally to a semiconductor integrated circuit.

### BACKGROUND

Conventionally, a built-in self test (hereinafter referred to as BIST) circuit is built in a semiconductor integrated circuit including a memory. The BIST is performed by the BIST circuit, and then determination of the presence or absence of a fault and identification of a fault position are performed.

### BRIEF DESCRIPTION OF THE DRAWINGS

FIG. 1 is a diagram illustrating a schematic configuration of a semiconductor integrated circuit according to an embodiment;

FIG. 2 is a diagram illustrating an example of constituent elements included in a memory output analysis circuit and wiring lines between the constituent elements according to the embodiment;

FIG. 3 is a diagram illustrating an example of a configuration of the constituent elements of the memory output analysis circuit according to the embodiment;

FIG. 4 is a diagram illustrating an example of constituent elements included in a diagnostic data storage circuit according to the embodiment;

FIG. 5 is a diagram for explaining an example of a shift register formed by registers according to the embodiment;

FIG. 6 is a flowchart for explaining an operation of the semiconductor integrated circuit according to the embodiment;

FIG. 7 illustrates an example of a procedure of performing the BIST according to the embodiment; and

FIG. 8 illustrates another example of the procedure of performing the BIST according to the embodiment.

### DETAILED DESCRIPTION

According to an embodiment, a semiconductor integrated circuit includes a memory, a built-in self test circuit, and a memory output analysis circuit. The built-in self test circuit writes data into each row of the memory, causes the memory to output data, and outputs an expected value. The memory output analysis circuit includes a first circuit, a second circuit, and a third circuit. The first circuit determines the presence or absence of a first fault based on a comparison between data outputted from the memory and an expected value. The second circuit determines whether or not the first fault corresponds to a second fault that continues in an address direction when the first fault is detected by the first circuit and outputs a first signal when determining that the first fault corresponds to the second fault. The third circuit determines whether or not a third fault that does not correspond to the second fault occurs besides the second fault while the first signal is being outputted and outputs a second signal when determining that the third fault occurs. The built-in self test circuit determines whether or not to interrupt a test based on at least the first signal and the second signal.

Hereinafter, the semiconductor integrated circuit according to the embodiment will be described in detail with reference to the accompanying drawings. The present invention is not limited by the embodiment.

### First Embodiment

### Embodiment

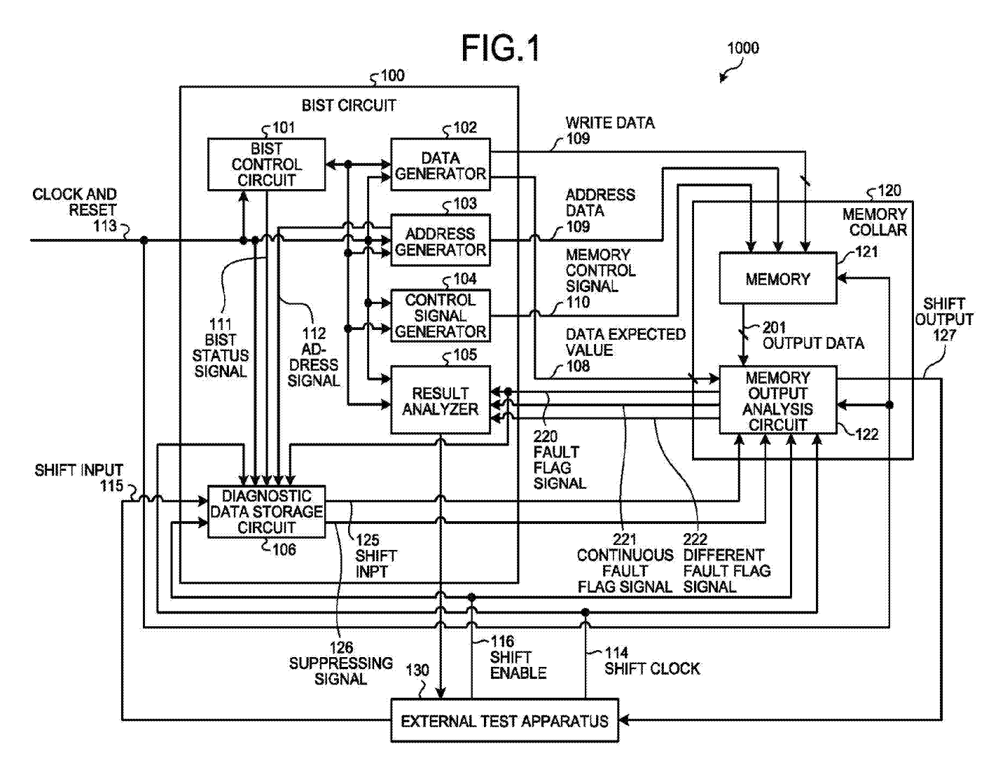

FIG. 1 is a diagram illustrating a schematic configuration of the semiconductor integrated circuit according to the embodiment. The semiconductor integrated circuit 1000 has a BIST circuit 100 and a memory collar 120. The BIST circuit 100 has a BIST control circuit 101, a data generator 102, an address generator 103, a control signal generator 104, a result analyzer 105, and a diagnostic data storage circuit 106.

The memory collar 120 has a memory 121, which is a BIST target, and a memory output analysis circuit 122.

In the BIST circuit 100, clock signal and reset signal 113 are inputted into the BIST control circuit 101, the data generator 102, the address generator 103, the control signal generator 104, the result analyzer 105, and the diagnostic data storage circuit 106.

A BIST result. 117 outputted from the result analyzer 105 is given to an external test apparatus 130. The external test apparatus 130 is connected with a shift input 115 and a shift output 127 and performs shift control of a shift path (described later) from the shift input 115 to the shift output 127, which is formed by various registers. The external test apparatus 130 performs the shift control by using a shift clock 114 and shift enable signal 116.

The clock signal and reset signal 113 are also inputted into the memory 121 and the memory output analysis circuit 122. The shift clock 114 is also inputted into the diagnostic data storage circuit 106 and the memory output analysis circuit 122.

The BIST control circuit 101 acquires a fault flag signal 220, a continuous fault flag signal 221, and a different fault flag signal 222 outputted from the memory output analysis circuit 122 through the result analyzer 105. The BIST control circuit 101 controls a diagnostic sequence including execution, interruption, and restart of the BIST based on the acquired fault flag signal 220, continuous fault flag signal 221, and the different fault flag signal 222.

In the diagnostic sequence, the BIST control circuit 101 controls operations of the data generator 102, the address generator 103, the control signal generator 104, the result analyzer 105, and the diagnostic data storage circuit 106, and causes these to generate signals necessary to perform various processing.

Write data 107 generated by the data generator 102, address data 109 generated by the address generator 103, and a memory control signal 110 generated by the control signal generator 104 are given to the memory 121. Thereby, data are written to the memory 121.

Data (output data 201) is outputted from the memory 121 according to the memory control signal 110 generated by the control signal generator 104. The output data 201 is inputted into the memory output analysis circuit 122.

A data expected value 108 that is the same as the write data 107 generated by the data generator 102 is given to the memory output analysis circuit 122, and it is determined whether or not the output data 201 outputted from the memory 121 coincides with the data expected value 108, that is, whether there is a fault or not.

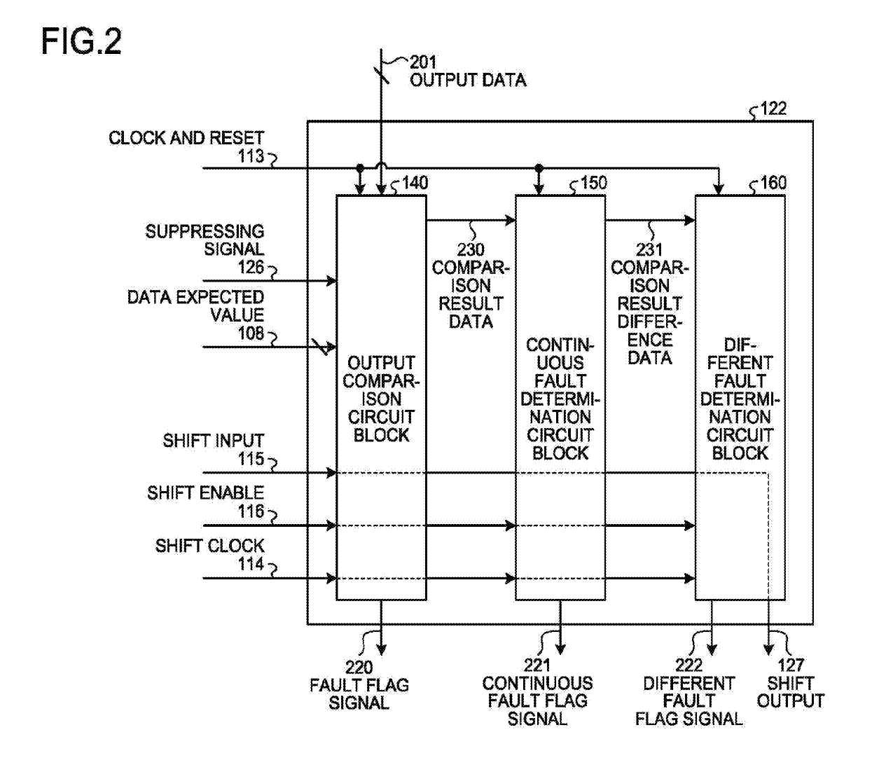

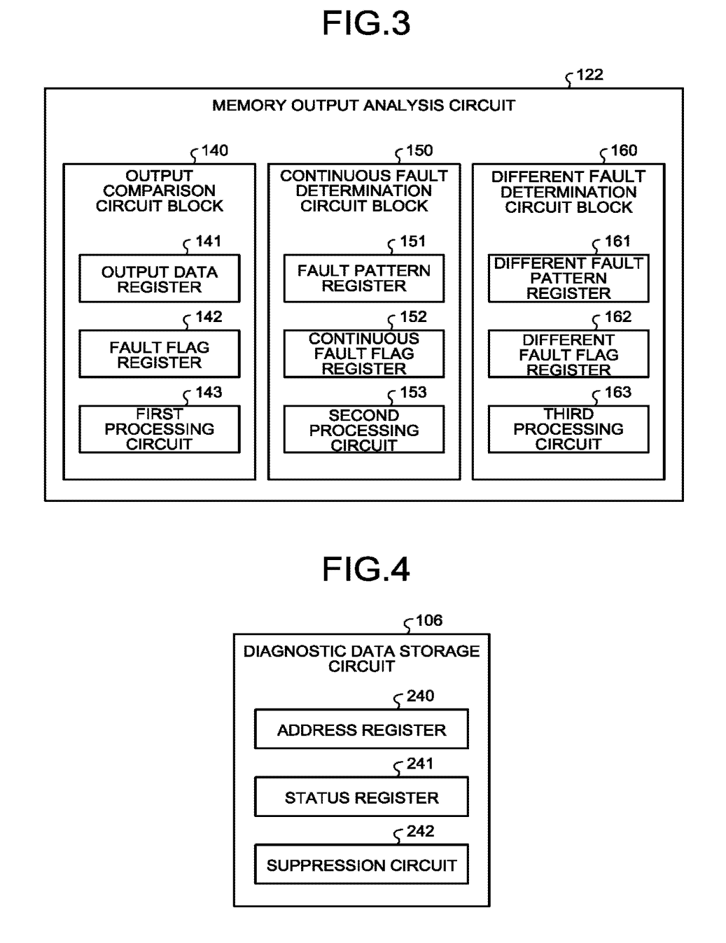

Next, a configuration example of the memory output analysis circuit 122 will be described with reference to FIG. 2 and FIG. 3. FIG. 2 is a diagram illustrating an example of constituent elements included in the memory output analysis circuit 122 and wiring lines between the constituent elements according to the embodiment. FIG. 3 is a diagram illustrating an example of a configuration of the constituent elements of the memory output analysis circuit 122 according to the embodiment.

As illustrated in FIG. 2, the memory output analysis circuit 122 has an output comparison circuit block 140, a continuous fault determination circuit block 150, and a different fault determination circuit block 160. The clock signal and reset signal 113 are commonly inputted into the output comparison circuit block 140, the continuous fault determination circuit block 150, and the different fault determination circuit block 160, and these blocks operate based on the clock signal and reset signal 113

The output data 201, the data expected value 108, and a suppressing signal 126 are inputted into the output comparison circuit block 140.

As illustrated in FIG. 3, the output comparison circuit block 140 has an output data register 141, a fault flag register 142, and a first processing circuit 143.

The output data 201 inputted into the output comparison circuit block 140 is taken into the output data register 141. The first processing circuit 143 compares the output data 201 taken into the output data register 141 with the data expected value 108.

The first processing circuit 143 operates the fault flag that indicates whether or not a fault is detected based on a result of the comparison performed by the first processing circuit 143.

A method of the comparison performed by the first processing circuit 143 and a concrete method of the operation of the fault flag are not limited to specific methods. A logic of the fault flag can be arbitrarily set.

Here, as an example, a fault flag whose logic is “1” indicates that a fault is detected. Setting logic of the fault flag to “1” may be written as setting the fault flag on. A fault flag whose logic is “0” indicates that no fault is detected. Setting logic of the fault flag to “0” may be written as setting the fault flag off.

In this case, the first processing circuit 143 performs, for example, a bit operation of exclusive OR of the output data 201 and the data expected value 108. By the bit operation of exclusive OR, data (comparison result data) is obtained whose bit width is the same as those of the output data 201 and the data expected value 108 and where bits whose values are different between the output data 201 and the data expected value 108 are set to “1” and bits whose values are the same between the output data 201 and the data expected value 108 are set to “0”.

The data where bits whose values are different between the output data 201 and the data expected value 108 are set to “1” and bits whose values are the same between the output data and the data expected value 108 are set to “0” is also referred to as a fault pattern, meaning that the data shows fault positions, in the present specification.

The first processing circuit 143 further calculates a logical sum of all bits of the comparison result data (fault pattern). Thereby, one bit data is obtained which is “1” when there is a different value bit between the output data 201 and the data expected value 108 and which is “0” when there is no different value bit between the output data 201 and the data expected value 108. The first processing circuit 142 stores a calculation result of the logical sum into the fault flag register 142 as the fault flag.

Thereby, when there is a different value bit between the output data 201 and the data expected value 108, the logic of the fault flag can be set to “1”, and when there is no different value bit between the output data 201 and the data expected value 108, the logic of the fault flag can be set to “0”.

The fault flag register 142 outputs the fault flag as the fault flag signal 220.

When the suppressing signal 126 indicates a suppression instruction, the first processing circuit 143 skips fault detection processing. When the suppressing signal 126 is logic that indicates a non-suppression instruction, the first processing circuit 143 can determine a value of the fault flag according to a comparison result between the output data and the data expected value 108.

Regarding the suppressing signal 126, the logic that indicates a suppression instruction and the logic that indicates a non-suppression instruction can be arbitrarily set.

As illustrated in FIG. 2, the comparison result data (comparison result data 230) obtained by the first processing circuit 143, that is, the fault pattern, is also inputted into the continuous fault determination circuit block 150.

As illustrated in FIG. 3, the continuous a determination circuit block 150 has a fault pattern register 151, a continuous fault flag register 152, and a second processing circuit 153.

When the fault flag changes from logic “0” to logic “1”, the comparison result data 230 inputted into the continuous fault determination circuit block 150 is stored in the fault pattern register 151.

When new comparison result data 230 is transmitted to the second processing circuit 153 after the comparison result data 230 is stored in the fault pattern register 151, the second processing circuit 153 compares the comparison result data 230 (hereinafter referred to as a stored pattern) stored in the fault pattern register 151 with the newly transmitted comparison result data 230.

Then, the second processing circuit 153 operates a continuous fault flag that indicates whether or not a continuous fault occurs based on a comparison between the stored pattern and the newly transmitted comparison result data 230.

Here, the BIST is performed for each row of the memory 121. Specifically, after the test is performed on one row of the memory 121, a test position is advanced to the next row whose address is next to that of the one row.

Therefore, in a case where faults are detected, when a fault position indicated by the stored pattern coincides with a fault position indicated by the newly transmitted comparison result data 230, it means that a continuous fault where fault positions continue in an address direction (row direction) occurs.

When bits corresponding to all bits that are “1 (fault)” in the stored pattern are “1” in the newly transmitted comparison result data 230, the second processing circuit 153 sets the continuous fault flag to logic indicating that a continuous fault occurs.

The logic of the continuous fault flag can be arbitrarily set. Here, the continuous fault flag of logic “1” indicates that a continuous fault occurs. Setting logic of the continuous fault flag to “1” may be written as setting the continuous fault flag on. The continuous fault flag of logic “0” indicates that no continuous fault occurs. Setting logic of the continuous fault flag to “0” may be written as setting the continuous fault flag off.

Thereby, while the continuous fault flag is on, the fault pattern stored in the fault pattern register 151 can be regarded as a pattern that indicates positions of faults continuing in the address direction (a continuous fault pattern).

When no fault is detected, the continuous fault flag is set to off.

The continuous fault flag register 152 holds the continuous fault flag. The continuous fault flag register 152 outputs the continuous fault flag as the continuous fault flag signal 221.

Further, when the fault pattern (continuous fault pattern) is stored in the fault pattern register 151, the second processing circuit 153 calculates a difference between the newly transmitted comparison result data 230 and the continuous fault pattern. Thereby, when a fault newly occurs at a position different from the faults included in the continuous fault, data (comparison result difference data) is obtained where a bit corresponding to the position of the fault that newly occurs is set to “1” and the other bits are set to “0”.

As illustrated in FIG. 2, the comparison result difference data obtained by the second processing circuit 153 is inputted into the different fault determination circuit block 160 as comparison result difference data 231.

As illustrated in FIG. 3, the different fault determination circuit block 160 has a different fault pattern register 161, a different fault flag register 162, and a third processing circuit 163.

The comparison result difference data 231 inputted into the different fault determination circuit block 160 is taken into the different fault pattern register 161.

The comparison result difference data 231 inputted into the different fault determination circuit block 160 is also inputted into the third processing circuit 163. The third processing circuit 163 operates a different fault flag that indicates whether or not a fault (other fault, different fault) different from the faults included in the continuous fault is detected based on the inputted comparison result difference data 231.

The logic of the different fault flag can be arbitrarily set. Here, as an example, the different fault flag whose logic is “1” indicates that the different fault is detected. Setting logic of the different fault flag to “1” may be written as setting the different fault flag on. The different fault flag of logic “0” indicates that no other fault is detected. Setting logic of the different fault flag to “0” may be written as setting the different fault flag off.

In this case, for example, the third processing circuit 163 calculates a logical sum of all bits of the inputted comparison result difference data 231. Thereby, one bit data is obtained which is “1” when there is the different fault and which is “0” when there is no other fault.

The different fault flag register 162 holds the different fault flag. The different fault flag register 162 outputs the different fault flag as the different fault flag signal 222.

The output data register 141, the fault flag register 142, the fault pattern register 151, the continuous fault flag register 152, the different fault pattern register 161, and the different fault flag register 162 become in a shift mode when the shift enable signal 116 becomes, for example, logic “1”. The shift mode will he described later.

FIG. 4 is a diagram illustrating an example of constituent elements included in the diagnostic data storage circuit 106 according to the embodiment. As illustrated in FIG. 4, the diagnostic data storage circuit 106 includes an address register 240, a status register 241, and a suppression circuit 242.

An address signal 112 outputted from the address generator 103 and a BIST status signal 111 outputted from the BIST control circuit 101 are inputted into the diagnostic data storage circuit 106. The fault flag signal 220 outputted from the memory output analysis circuit 122 is inputted into the diagnostic data storage circuit 106.

The suppression circuit 242 brings the address signal 112 into the address register 240 and brings the BIST status signal ill into the status register 241. When the BIST is interrupted, the suppression circuit 242 creates a state where the address register 240 and the status register 241 cannot be updated. Thereby, a test position when the BIST is interrupted and a state of the BIST at that time are stored.

Thereafter, when the BIST is restarted (from the top position of the memory 121) by the BIST control circuit 101, the suppression circuit 242 outputs logic (for example “0”) indicating a suppression instruction as the suppressing signal 126.

After the BIST is restarted, the suppression circuit 212 compares the address signals 112 that are sequentially inputted with address data stored in the address register 240. Similarly, the suppression circuit 242 compares the BIST status signals 111 that are sequentially inputted with status data stored in the status register 241.

When the inputted address signal 112 coincides with the address data stored in the address register 240 and the inputted BIST:status signal 111 coincides with the status data stored in the status register 241, the suppression circuit 242 outputs logic (for example “1”) indicating a non-suppression instruction as the suppressing signal 126.

In summary, when a fault is detected and the BIST is restarted from the beginning, the suppression circuit 242 suppresses detection of a fault until the test position reaches a position where the fault is detected last.

When the shift enable signal 116 becomes, for example, logic “1”, the address register 240 and the status register 241 enter the shift mode.

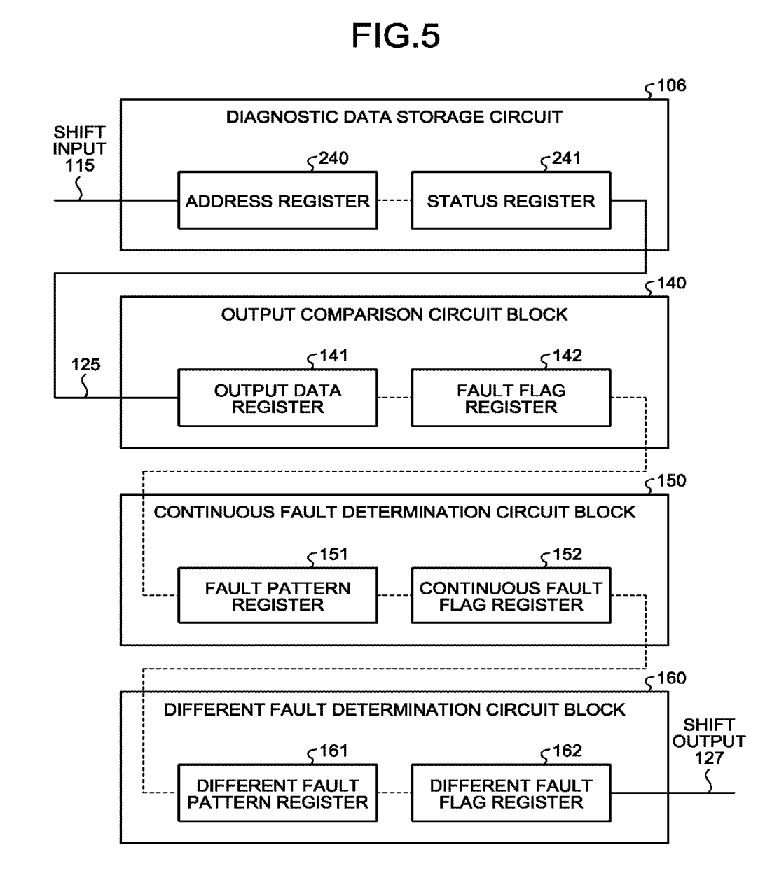

FIG. 5 is a diagram for explaining an example of a shift register formed by registers according to the embodiment. In the shift mode, as illustrated in FIG. 5, the address register 240, the status register 241, the output data register 141, the fault flag register 142, the fault pattern register 151, the continuous fault flag register 152, the different fault pattern register 161, and the different fault flag register 16 form a shift register from the shift input 115 to the shift output 127.

In the shift mode, each register shifts out its own content according to the shift clock 114.

The shift register forms a circulative shift path. When fault information is outputted, values of the registers are shifted out. The shift path is circulatively formed, so that each register can return to a state where the BIST is interrupted when the shift out is completed.

Further, it is possible to take out the address signal 112, the BIST status signal 111, an output from the memory 121, the fault flag, the continuous fault pattern, the continuous fault flag, the different fault pattern, and the different fault flag at a time when a fault is detected to the outside, and observe these by inputting these into the external test apparatus 130.

Hereinafter, the address signal 112, the BIST status signal 111, an output from the memory 121, the fault flag, the continuous fault pattern, the continuous fault flag, the different fault pattern, and the different fault flag at a time when a fault is detected, which are outputted from the shift register, may be collectively referred to as fault information.

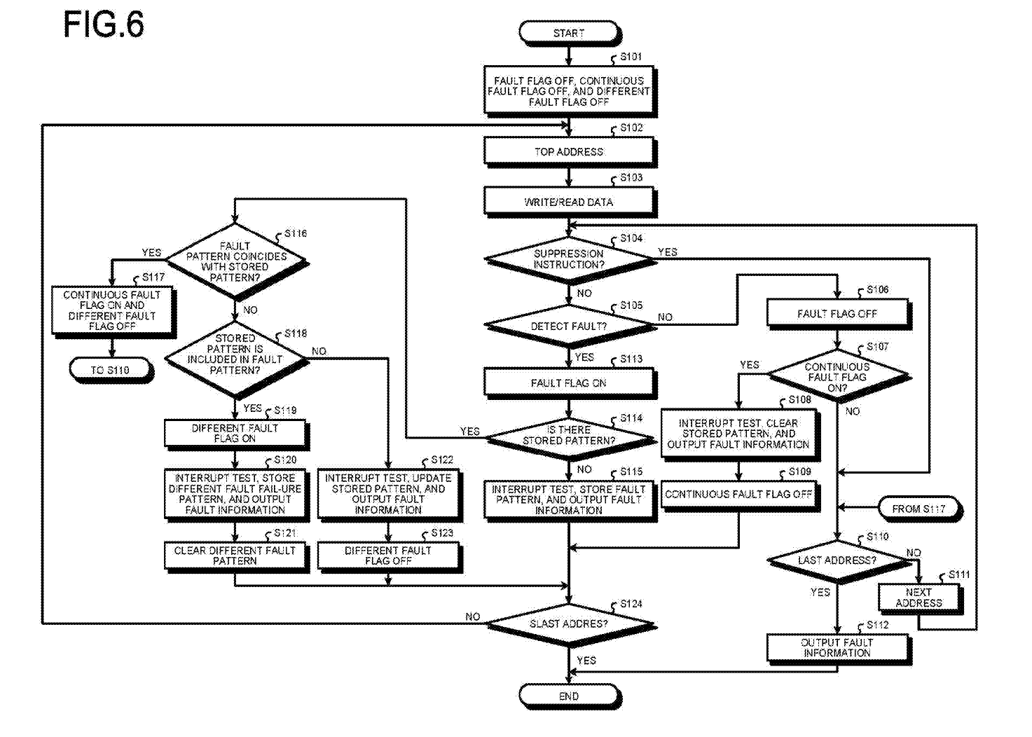

Next, an operation of the semiconductor integrated circuit 1000 according to the embodiment will be described. FIG. 6 is a flowchart for explaining the operation of the semiconductor integrated circuit 1000 according to the embodiment.

As illustrated in FIG. 6, when starting the BIST, all of the fault flag register 142, the continuous fault flag register 152, and the different fault flag register 162 are reset, and the corresponding flags are set to off (S101).

The BIST control circuit 101 sets the top position of the memory 121 as the test position by causing the address generator 103 to generate an address of the top row (top address) of the memory 121 (S102).

Then, writing and reading of data is performed on the test position by the data generator 102 and the control signal generator 104 (S103).

The output data 201 that is read from the test position and outputted from the memory 121 and the data expected value 108 generated by the data generator 102 are inputted into the output comparison circuit block 140 of the memory output analysis circuit 122. The output data 201 is taken into the output data register 141.

When the suppressing signal 126 indicates a non-suppression instruction (S104, Yes), fault detection is performed (S105).

Specifically, the first processing circuit 143 compares the output data 201 taken into the output data register 141 with the data expected value 108. The first processing circuit 143 operates the fault flag based n the result of the comparison

When no fault is detected (S105, No), that is, for example, when the comparison result data obtained by comparison between the output data and the data expected value 108 is all zeros, the first processing circuit 143 sets the fault flag off (S106). That is, the first processing circuit 143 stores, for example, logic “0” into the fault flag register 142, and the fault flag indicates logic “0”.

When the fault flag is set to off (S106), the BIST control circuit 101 determines whether or not the continuous fault flag is on (S107).

When it is determined that the continuous fault flag is on (S107, Yes), the BIST control circuit 101 interrupts test (BIST) and outputs fault information (S108). In this case, the fault pattern stored in the fault pattern register 151 is cleared. Further, the continuous fault flag is set to off (S109).

When the fault information is outputted, for example, the shift register, which includes the address register 240, the status register 241, the output data register 141, the fault flag register 142, the fault pattern register 151, the continuous fault flag register 152, the different fault pattern register 161, and the different fault flag register 162, shifts out values held by these registers. For example, the BIST control circuit. 101 instructs the external test apparatus 130 to operate the shift enable signal 116 through the result analyzer 105, and transfers these registers to the shift mode.

After the processing of S109, the BIST control circuit 101 performs processing of S224. The processing of S224 will be described later.

In the processing of S107, when it is determined that the continuous fault flag is off (S107, No), the BIST control circuit 101 determines whether or not the test position reaches a position indicated by the last address of the memory 121 (S110). Whether or not the test position reaches the position indicated by the last address of the memory 121 can be confirmed by, for example, determining whether or not an address that is finally generated by the address generator 103 is the last address.

When it is determined that the test position does not reach the position indicated by the last address of the memory 121 (S110, No), the BIST control circuit 101 sets the test position to a row following the current position by instructing the address generator 103 to generate an address of the next row (S111). Then, control shifts to the processing of S103.

In the processing of S110, when it is determined that the test position reaches the position indicated by the last address of the memory 121 (S110, Yes), the BIST control circuit 101 outputs fault information (S112) and the BIST is completed.

In the processing of S104, when the suppressing signal 126 indicates a suppression instruction (S103, No), the control shifts to the processing of S110.

In short, when the suppressing signal 126 indicates a suppression instruction, the detection of fault is skipped, and the test position is set to the next row or the BIST is completed.

In the processing of S105, when a fault is detected (S105, Yes), that is, for example, when the comparison result data obtained by comparison between the output data 201 and the data expected value 108 is not all zeros, the first processing circuit 143 sets the fault flag on (S113). The first processing circuit 143 stores, for example, logic “1” into the fault flag register 142.

The processing thereafter changes depending on whether or not the fault pattern is stored in the fault pattern register 151.

When the fault pattern is not stored (S114, No), the BIST control circuit 101 interrupts the test and outputs fault information (S115). In the continuous fault determination circuit block 110, the fault pattern register 151 takes in the comparison result data 230. In other words, the fault pattern is stored in the fault pattern register 151. In S115, the comparison result data 230 held in the fault pattern register 151 is outputted as the fault pattern by the shift out.

A method of determining whether or not the fault pattern is stored is not limited to a specific method. In an example, the BIST control circuit 101 may determine whether or not fault detection at this time is the first detection based on timing when the logic of the fault flag shifts from “0” to “1”. In another example, an arbitrary circuit may notify the BIST control circuit 101 whether or not the fault pattern is stored.

After the processing of S115, the BIST control circuit 101 determines whether not the test position reaches the position indicated by the last address of the memory 121 (S124) in the same manner as in S210.

When it is determined that the test position does not reach the position indicated by the last address of the memory 121 (S124, No), the BIST control circuit 101 shifts to S102 and sets the test position to the top position of the memory 121.

When it is determined that the test position reaches the position indicated by the last address of the memory 121 (S124, Yes), the BIST is completed.

When the fault pattern is stored (S114, No), in the continuous fault determination circuit block 150, the second processing circuit 153 determines whether or not the fault pattern that is newly inputted as the comparison result data 230 coincides with the stored pattern (the fault pattern held in the fault pattern register 151) (S116).

When it is determined that the newly inputted fault pattern coincides with the stored pattern (S116, Yes), the second processing circuit 153 sets the continuous fault flag on and the third processing circuit 163 sets the different fault flag off based on the comparison result difference data 231 (S117). Then, the control shifts to the processing of S110.

When it is determined that the fault pattern does not coincide with the stored pattern (S116, No), the second processing circuit 153 determines whether or not the stored pattern is included in the newly inputted fault pattern S118).

When all bits that are “1 (fault)” in the stored pattern are “1 (fault)” in corresponding bits of newly transmitted fault data, the second processing circuit 153 determines that the stored pattern is included in the newly inputted fault pattern (S118, Yes). In this case, the comparison result difference data 231 is transmitted to the different fault determination circuit block 160, and the third processing circuit 163 sets the different fault flag on based on the comparison result difference data 231 (S119).

When the different fault flag is set on, the BIST control circuit 101 interrupts the test and outputs fault information (S120). The comparison result difference data 231 that is inputted into the different fault determination circuit block 160 is stored in the different fault pattern register 161 as the different fault pattern. In 3120, the different fault pattern is outputted by the shift out.

The third processing circuit 163 clears the different fault pattern register 161 (S121) and the control shifts to the processing of S124.

When some or all bits that are “1 (fault)” in the stored pattern are “C (normal)” in corresponding bits of the newly transmitted fault data, the second processing circuit 153 determines that the stored pattern is not included in the newly inputted fault pattern 113, No).

In this case, the BIST control circuit 101 interrupts the test and outputs fault information (3122). In the continuous fault determination circuit block 150, the fault pattern register 151 takes in the comparison result data 230. In other words, content of the fault pattern register 151 is updated with new fault data. In S119, the new fault data is outputted as an updated fault pattern by the shift out.

The third processing circuit 163 sets the different fault flag off (S123). Then, the control shifts to the processing of S124.

The external test apparatus 130 creates a fail bit map based on obtained fault information.

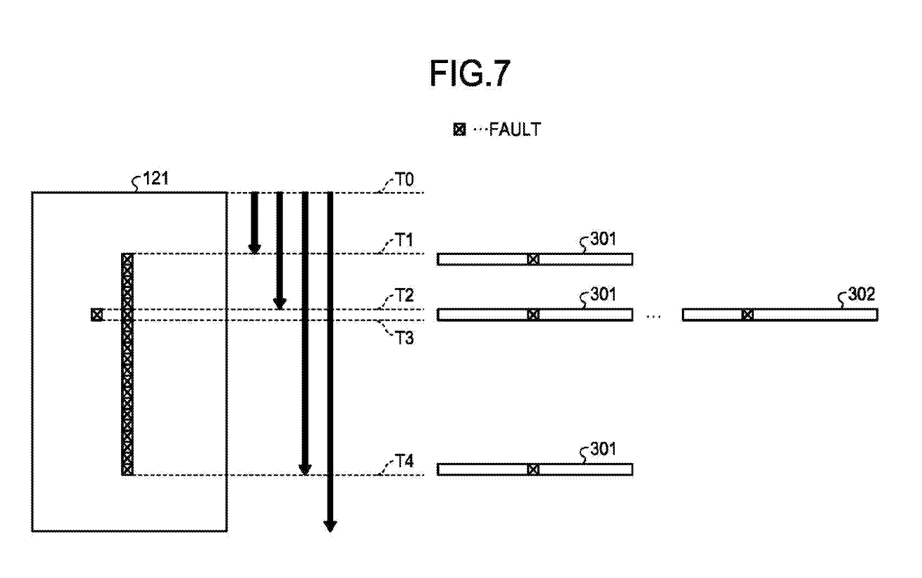

FIG. 7 illustrates an example of a procedure of performing the BIST according to the embodiment.

The semiconductor integrated circuit 1000 starts the BIST at time T0.

When a fault is detected at time T1, by the processing of S115, the semiconductor integrated circuit 1000 stores a fault pattern 301 in the fault pattern register and interrupts the BIST. Then, the semiconductor integrated circuit 1000 outputs fault information to the external test apparatus 130.

Here, the semiconductor integrated circuit 1000 stores the address signal 112 and the BIST status signal 111 of when the fault is detected into a corresponding register of the address register 240 and the status register 241. Thereafter, the semiconductor integrated circuit 1000 restarts the BIST from time T0.

After the BIST is restarted, a suppression instruction is outputted until time T1, so that the semiconductor integrated circuit 1000 does not determine that a fault is detected until time T1.

The same fault pattern continues from time T1 to time T2. In other words, the comparison result data 230 coincides with the fault pattern 301 stored in the fault pattern register. Therefore, the semiconductor integrated circuit 1000 sets the continuous fault flag on by the processing of S117 and advances the BIST.

When it reaches time T2, the semiconductor integrated circuit 1000 obtains a fault pattern where the different fault different from the fault pattern (continuous fault pattern) 301 stored in the fault pattern register 151 occurs. Therefore, the semiconductor integrated circuit 1000 sets the different fault flag on by the processing of S119. Then, the semiconductor integrated circuit 1000 stores the different fault pattern 302 that indicates a position of fault (other fault, different fault) different from the fault pattern 301. Then, the semiconductor integrated circuit 1000 interrupts the BIST by the processing of S120 and outputs fault information to the external test apparatus 130. Then, the semiconductor integrated circuit 1000 restarts the BIST from time T0.

After the restart, when it reaches time T3, the different fault is not detected, and the semiconductor integrated circuit 1000 obtains again the same fault pattern as the fault pattern (continuous fault pattern) 301 held in the fault pattern register 151. Therefore, the semiconductor integrated circuit 1000 maintains a state where the continuous fault flag is set on and sets the different fault flag off by the processing of S117. Then, the semiconductor integrated circuit 1000 continues the BIST.

Thereafter, when it reaches time T4, the normal output data 201 is outputted. However, the continuous fault flag is on, so that the semiconductor integrated circuit 1000 interrupts the BIST by the processing of S108 and outputs fault information to the external test apparatus 130. Then, the semiconductor integrated circuit 1000 sets the continuous fault flag off by the processing of S109. Then, the semiconductor integrated circuit 1000 restarts the BIST from time T0.

As described above, according to the embodiment, the output comparison circuit block 140 determines the presence or absence of a fault based on the comparison between the output data 201 and the data expected value 108 105). When a fault is detected by the output comparison circuit block 140 (S105: Yes), the continuous fault determination circuit block 150 determines whether or not the fault corresponds to a continuous fault where the fault continues in the address direction (S116). When it is determined that the fault detected by the output comparison circuit block 140 corresponds to the continuous fault S116: Yes), the continuous fault determination circuit block 150 sets the continuous fault flag on (S117). The different fault determination circuit block 160 determines whether or not another fault occurs in addition to the continuous fault. When it is determined that another fault occurs in addition to the continuous fault (S118: Yes), the different fault determination circuit block 160 sets the different fault flag on (S119). The BIST circuit 100 determines whether or not to interrupt the BIST based on at least the continuous fault flag and the different fault flag.

Thereby, it is possible to shorten a diagnosis time.

Specifically, when the different fault flag is set on, the BIST circuit 100 interrupts the test (FIGS. 6: S119 and S120, FIG. 7: time T2). When the different fault flag is set off in a case where the continuous fault flag is on, the BIST circuit 100 does not interrupt the BIST but continues the BIST (FIGS. 6: S117, S110, and S111, FIG. 7: time T4).

Thereby, it is possible to reduce the number of times of interrupting the BIST, so that the diagnosis time is shortened.

Further, when restarting the BIST, the BIST circuit 100 suppresses detection of a fault by the suppressing signal 126 until the test position reaches the position where the fault is detected last.

Thereby, the diagnosis can be performed without detecting again a fault that has been detected before, so that the diagnosis time is shortened. Further, it is possible to acquire information of all the faults. Further, it is possible to advance the test position without often interrupting and restarting the BIST for the same fault.

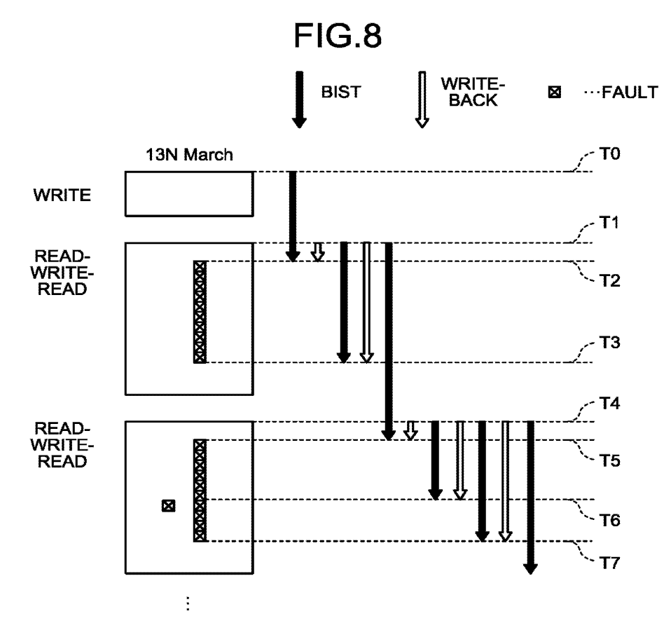

It should be understood that the embodiment described above is an example and is not limited. For example, in the embodiment described above, when the BIST is restarted, the BIST is performed from the beginning. However, the BIST need not be performed from the beginning. A case where a BIST (march test) called a marching pattern named 13N is performed will be described as an example with reference to FIG. 8.

Here, the marching pattern is, for example, a pattern where an operation (march element r0w1r1) in which logic “0” is read from a memory in a state of logic “0”, logic “1” is written, and logic “1” is read is sequentially performed on all addresses, and the state of the memory is changed from the logic “0” to the logic “1”.

First, the semiconductor integrated circuit 1000 starts the BIST as a WRITE operation from time T0 and writes a predetermined data pattern to all addresses of the memory 121.

Next, as a READ-WRITE-READ operation, the semiconductor integrated circuit 1000 performs reading of a normal data pattern (for example, 1010), writing of a reverse data pattern (for example, 0101), and reading of the reverse data pattern in each address in the ascending order of the addresses. Next, the semiconductor integrated circuit 1000 performs reading of the reverse data pattern, writing of the normal data pattern, and reading of the normal data pattern in each address in the ascending order of the addresses.

Further, the semiconductor integrated circuit 1000 performs reading of the normal data pattern and writing of the reverse data pattern in each address in the descending order of the addresses, and subsequently performs reading of the reverse data pattern and writing of the normal data pattern in each address in the descending order of the addresses.

At time T2, a first fault is detected. There is no stored pattern, so that the semiconductor integrated circuit 1000 interrupts the BIST, outputs fault information, and restarts the BIST. At this time, the time to which it should be traced back is time T1 which is a discontinuity of the marching operation.

Here, it should be noted that when the BIST being performed is the marching, data in an address at the traced back time (time T1) has been already rewritten to different data where the normal pattern and the reverse pattern are exchanged, so that a correct operation is not performed in the marching test in which a reading operation based on the state before being rewritten is performed.

Therefore, the semiconductor integrated circuit 1000 writes back the data from the time point (time T1) to which the address is traced back to the time point (time T2) at which the BIST is interrupted. The write-back is performed between time T1 and time T2, and the BIST is restarted after the time returns to time T1 again.

After the BIST is restarted, no fault is detected until time T2. From time T2 to time T3, the same fault pattern continues (coincides with the stored pattern), so that the semiconductor integrated circuit 1000 sets the continuous fault flag on and does not interrupt the BIST.

At time T3, normal data is outputted. Therefore, the semiconductor integrated circuit 1000 interrupts the BIST and outputs fault information. Then, the time is traced back to the position of time T1, the write-back is performed between time T1 and time T3, and the BIST is restarted after the time returns to time T1 again.

Thereafter, a fault is detected at time T5. The stored pattern is cleared and does not exist, so that the semiconductor integrated circuit 1000 interrupts the BIST, outputs fault information, and restarts the BIST. At this time, the time to which it should be traced back is time T4 which is a discontinuity of the marching operation. The write-back is performed between time T4 and time T5, and the BIST is restarted after the time returns to time T4 again.

After the BIST is restarted, a fault is not detected until time T5. From time T5 to time T6, the same fault pattern continues (coincides with the stored pattern), so that the semiconductor integrated circuit 1000 sets the continuous fault flag on and does not interrupt the BIST.

At time T6, the different fault different from the stored pattern (continuous fault pattern) is detected. Therefore, the semiconductor integrated circuit 1000 sets the different fault flag on and interrupts the BIST. Then, the time is traced back to time T4, the write-back is performed between time T4 and time T6, and the BIST is restarted after the time returns to time T4 again.

After the BIST is restarted, normal data is outputted at time T7. Therefore, the semiconductor integrated circuit 1000 interrupts the BIST and outputs fault information. Then, the time is traced back to the position of time T4, the write-back is performed between time T4 and time T6, and the BIST is restarted after the time returns to time T4 again.

Thereafter, when no new fault is detected, the BIST is completed.

In this way, when the BIST is performed again, the BIST does not return to the first time point, so that it is possible to shorten the diagnosis time.

In a walking test in which data is not rewritten in a different way from the marching pattern and the BIST advances while the data is still in the previous state, data need not be written hack, so that the BIST may be restarted immediately after the traced back time point.

In the marching test, the BIST may return to the first time point every time the BIST is interrupted.

The time point to which it should be traced back when the BIST is restarted may be a time point traced back by a certain address from an interrupted time point instead of the discontinuity of the marching operation.

When one BIST circuit 100 tests a plurality of memories 121, a shift register may be formed by serially connecting the registers 141, 142, 151, 152, 161, and 162 in the memory output analysis circuit 122 provided in each memory 121.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
a memory;
a built-in self test circuit that writes data into each row of the memory, causes the memory to output data, and outputs an expected value; and
a memory output analysis circuit including
a first circuit that determines the presence or absence of a first fault based on a comparison between the data outputted from the memory and the expected value,
a second circuit that determines whether or not the first fault corresponds to a second fault that continues in an address direction when the first fault is detected by the first circuit and outputs a first signal when determining that the first fault corresponds to the second fault, and
a third circuit that determines whether or not a third fault that does not correspond to the second fault occurs besides the second fault while the first signal is being outputted and outputs a second signal when determining that the third fault occurs,
wherein the built-in self test circuit determines whether or not to interrupt a test based on at least the first signal and the second signal.

2. The semiconductor integrated circuit according to claim 1, wherein
when the second signal is outputted, the built-in self test circuit interrupts the test and outputs fault information, and
while the first signal is being outputted, when the output of the second signal is stopped, the built-in self test circuit continues the test without interrupting the test.

3. The semiconductor integrated circuit according to claim 2, wherein
the built-in self test circuit interrupts test and outputs the fault information, and thereafter restarts the test from a restart position traced back from the interrupt position.

4. The semiconductor integrated circuit according to claim 3, wherein
the built-in self test circuit does not interrupt the test after storing the interrupt position and restarting the test until a test position reaches the interrupt position.
